(19) United States
(12) Patent Application Publication
(10) Pub. No.: US 2005/0064734 A1
(43) Pub. Date: Mar. 24, 2005

(54) Cable end connector assembly

(76) Inventors: Shih-Tung Chang, Tu-chen (TW); Xiaofeng Li, Kunsan (CN); Daoyuan Chen, Kunsan (CN); ZhenQiang Wu, Kunsan (CN)

Correspondence Address: WEI TE CHUNG;FOXCONN INTERNATIONAL, INC., 1650 MEMOREX DRIVE, SANTA CLARA, CA, 95050, US

(21) Appl. No.: 10/950,319

(22) Filed: Sep. 23, 2004

(30) Foreign Application Priority Data
Sep. 24, 2003 (TW) 92217126

(51) Int. Cl. H01R 12/00; H05K 1/00; H01R 13/66; H01R 33/945

(52) U.S. Cl. 439/63

(57) ABSTRACT

A cable end connector assembly (100) includes a cable end connector (2) having a metallic outer shell (21) shielding an outer surface thereof and a protector (1) having a receiving cavity (101) enclosing the metallic outer shell of the cable end connector.

### BACKGROUND OF THE INVENTION

1. Field of the Invention

The present invention generally relates to an electrical connector assembly and more particularly relates to a cable end connector assembly for high frequency application.

2. Description of the Related Art

Cable end connectors are often mounted in electronic appliances, such as personal digital assistants (PDA) and a notebook, used for transmitting radio-frequency (RF) signals. The cable end connector normally has a metallic shell for Electro Magnetic Interference (EMI) protection. Such a conventional cable end connector is, for example, disclosed in U.S. Pat. No. 6,508,668 B1. The cable end connector includes a dielectric member holding a central terminal within an outer conductive shell.

However, as the size of the electronic appliance decreases, it has become extremely desirable for connectors to have minimal dimensions. Therefore, the outer conductive shell of a small cable end connector usually has correspondingly small sized edges, corners and protruding barbs. These fine sharp edges, corners and barbs of the shell are easily to be scratched by exterior elements, and are also easily to scrape other interior elements of the electronic appliance, such as LCD, during transportation or when being mounted in the electronic appliance.

Hence, a need has existed for an improved cable end connector assembly for overcoming the disadvantages of the foregoing shortcomings.

### BRIEF SUMMARY OF THE INVENTION

A main object of the present invention is to provide a cable end connector assembly having a protector mean.

A cable end connector assembly comprises a cable end connector having a metallic outer shell and a protector enclosing the cable end connector. The protector includes a base portion having a receiving cavity and a cover integrally formed with the base portion. The metallic outer shell of the cable end connector is received in the receiving cavity. The cover is normally suspends above a front portion of the receiving cavity for covering the shell of the cable end connector.

Other objects, advantages and novel features of the invention will become more apparent from the following detailed description when taken in conjunction with the accompanying drawings.

### DESCRIPTION OF THE DRAWINGS

FIG. 1 is a perspective view of a cable end connector assembly in accordance with an embodiment of the present invention.

FIG. 2 is an exploded view of FIG. 1.

FIG. 3 is another exploded view of FIG. 1.

### DETAILED DESCRIPTION OF THE INVENTION

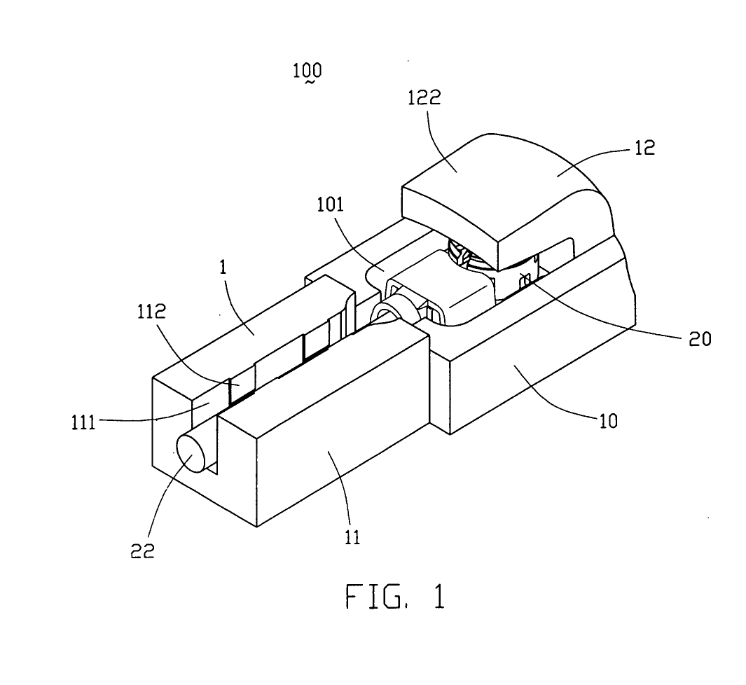

Referring to FIG. 1, a cable end connector assembly 100 according to the present invention is mounted in an electronic appliance, such as a PDA and a personal computer, and comprises a cable end connector 2 and a protector 1 receiving the cable end connector 2 therein.

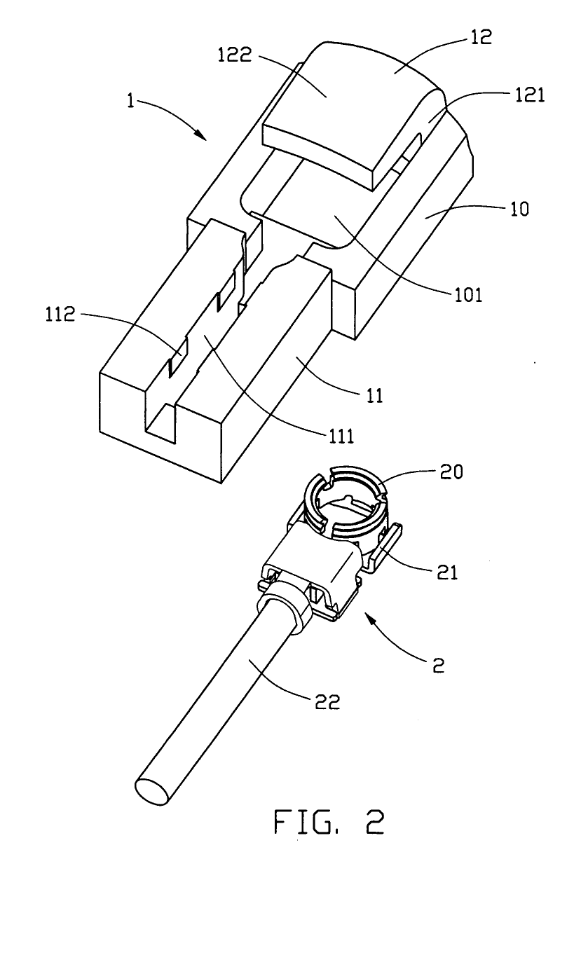

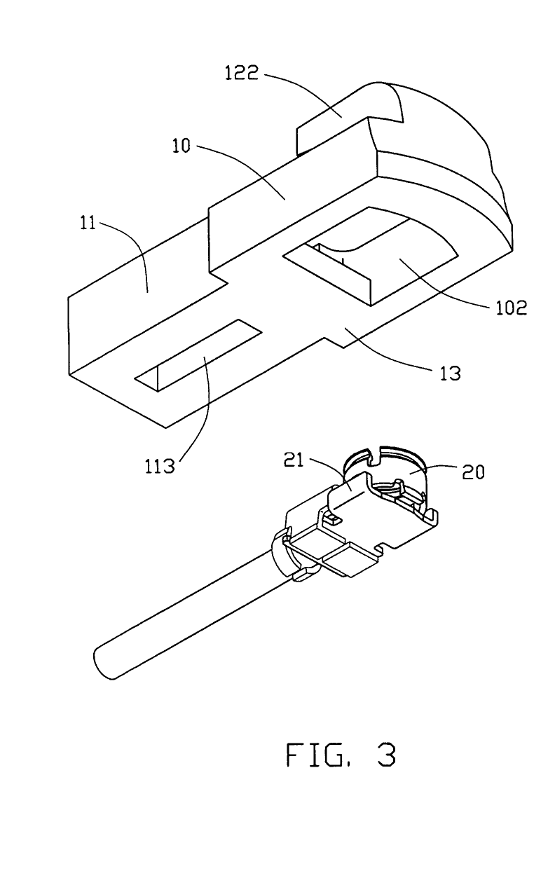

Referring to FIGS. 2 and 3, the cable end connector 2 has an generally L-shaped configuration and comprises a vertically extending head portion 20 for mating with a complementary member of an electrical device, a horizontally extending coaxial cable 22, and a metallic outer shell 21 shielding the head portion 20 and retaining the coaxial cable 22 to connect with the head portion 20. The cable end connector 2 can be any cable end connector having generally L-shaped configuration. In this preferred embodiment of the preset invention the cable end connector 2 is disclosed in U.S. Pat. No. 6,340,312 B1 issued on Jan. 22, 2002 and assigned to the same assignee as the present invention. The whole disclosures of the '312 patent is also incorporated herein by reference. A detailed description of the cable end connector 2 is omitted hereafter.

The protector 1 is a one-piece structure unitarily formed of elastic material such as rubber or the like. The protector 1 includes a substantially rectangular base portion 10, a longitudinally extending portion 11 extending rearwardly from a rear portion of the base portion 10 for holding the cable 22 of the cable end connector 2 therein, and a cover 12 integrally formed with the base portion 10. A receiving cavity 101 is sized and configured in a substantially central portion of the base portion 10 for receiving the head portion 20. A groove 111 is longitudinally defined in a middle portion of the extending portion and has a front end communicating with the receiving cavity 101. A plurality of retaining protrusions 112 inwardly project in the groove 111 for holding the cable 22 of the cable end connector 2. The cover 12 includes a substantially vertical transition portion 121 connecting to a front top surface of the base portion 10 and a horizontal shelter 122 extending rearwardly from the transition portion 121. The shelter 122 is spaced from an upper surface of the base portion 121 and normally extends above a front portion the receiving cavity 101. The protector 1 further has a bottom wall 13. The bottom wall 13 defines a first and a second opening 102, 113 respectively communicating with the receiving cavity 101 and the groove 111.

As best shown in FIG. 1 and in conjunction with FIGS. 2 and 3, in assembly, the cable end connector 2 is installed in the protector 1 after the shelter 122 is elastically lifted upwardly. The head portion 20 of the cable end connector 2 is received in the receiving cavity 101. The cable 22 of the cable end connector 2 is pressed into the groove 111 and is retained by the retaining protrusions 112 of the protector 1. The shelter 122 is released and returns to its normal position to enclose the head portion 20 in the receiving cavity 101. When the cable end connector is carried to be assembled to the electronic appliance, the shelter 122 of the protector 1 is pushed aside, and the cable end connector 2 is taken out of the protector 1 to electrically connect with a complementary connector (not shown) of the electronic appliance. Being protected by the protector 1, the shell 21 of the cable end connector 2 cannot touch the electronic appliance directly during carrying or assembling, thereby avoiding clashing with components of the electronic appliance.

It is to be understood, however, that even though numerous, characteristics and advantages of the present invention have been set fourth in the foregoing description, together with details of the structure and function of the invention, the disclosed is illustrative only, and changes may be made in detail, especially in matters of shape, size, and arrangement of parts within the principles of the invention to the full extent indicated by the broad general meaning of the terms in which the appended claims are expressed.

1. A cable end connector assembly comprising:
a cable end connector having a metallic outer shell shielding an outer surface thereof; and
a protector having a cavity receiving the metallic outer shell of the cable end connector.

2. The cable end connector assembly according to claim 1, wherein the protector includes a base portion, the receiving cavity being defined in the base portion, and a cover integrally formed with the base portion and covering the shell of the cable end connector.

3. The cable end connector assembly according to claim 2, wherein the cover includes a transition portion connecting to a front portion of the base portion and a shelter extending rearwardly from the transition portion, the shelter spaced from an upper surface of the base portion and suspending above the receiving cavity.

4. The cable end connector assembly according to claim 2, wherein the cover is elastically movable to permit installing the cable end connector in the protector.

5. The cable end connector assembly according to claim 1, wherein the cable end connector includes a cable, and wherein the protector has a groove communicating with the receiving cavity, the groove holding the cable therein.

6. The cable end connector assembly according to claim 5, wherein the groove forms an inwardly projecting protrusion for securing the cable of the cable end connector.

7. The cable end connector assembly according to claim 1, wherein the protector is a one-piece structure unitarily formed of elastic material.

8. A cable end connector assembly comprising:
a cable end connector having a metallic outer shell at one end and a cable extending outward at an opposite end; and
a protector defining a cavity and a groove communicating with each other; wherein the cavity receives the metallic outer shell and the groove receives a front portion of the cable, respectively.

9. The cable end connector assembly according to claim 8, wherein said cavity is defined in a rectangular base portion.

10. The cable end connector assembly according to claim 8, wherein said the protector further includes a cover essentially shielding the cavity.

11. The cable end connector assembly according to claim 10, wherein said cover is moveable to expose the cavity for easily loading/unloading the metallic outer shell.

12. The cable end connector assembly according to claim 8, wherein the metallic outer shell defines a mating port in a first direction, and the cable extends in a second direction perpendicular to said first direction.

13. The cable end connector assembly according to claim 12, wherein the protector further includes a cover essentially shielding the cavity in said first direction.

14. A cable end connector assembly comprising:
a connector housing section defining a mating opening for mating a complementary connector;
a cable section extending from a rear portion of the connector housing;
a protector defining a cavity circumferentially receiving the connector housing section.

15. The cable end connector assembly according to claim 14, wherein the mating opening is not exposed to an exterior.

16. The cable end connector assembly according to claim 15, wherein the protector further includes a cover to shield the mating opening.

17. The cable end connector assembly according to claim 16, wherein said cover is moveable to expose the cavity.

18. The cable end connector assembly according to claim 14, wherein said protector further defines a groove in communication with the cavity to receive a front portion of the cable.

19. The cable end connector assembly according to claim 18, wherein said mating opening faces an exterior in a first direction and the cable extends in a second direction perpendicular to said first direction.
